(19) United States
(12) Patent Application Publication
(10) Pub. No.: US 2009/0197075 A1
(43) Pub. Date: Aug. 6, 2009

(54) COATINGS AND COATING PROCESSES FOR MOLYBDENUM SUBSTRATES

(75) Inventors: Kirk C. Newton, Enfield, CT (US); Michael A. Kmetz, Colchester, CT (US)

Correspondence Address: BACHMAN & LAPOINTE, P.C. (P&W), 900 CHAPEL STREET, SUITE 1201, NEW HAVEN, CT, 06510-2802, US

(73) Assignee: UNITED TECHNOLOGIES CORPORATION, Hartford, CT (US)

(21) Appl. No.: 12/024,160

(22) Filed: Feb. 1, 2008

(51) Int. Cl. B32B 15/20; B32B 7/00; C23C 16/00; B05D 3/04

(52) U.S. Cl. 428/332; 428/446; 118/724; 427/337

(57) ABSTRACT

In a method for coating a molybdenum-based substrate, a molybdenum disilicide layer is formed on the substrate. Aluminum is reacted with hydrochloric gas to produce aluminum chloride. The aluminum chloride is reacted with hydrogen and carbon dioxide to produce alumina. A layer of the alumina is deposited atop the molybdenum disilicide layer.

### BACKGROUND

The disclosure relates to the fields of: aerospace casting cores; and aerospace molybdenum alloys. More particularly, the disclosure relates to coatings for such cores and/or alloys.

Investment casting is a commonly used technique for forming metallic components having complex geometries, especially hollow components, and is used in the fabrication of superalloy gas turbine engine components. The invention is described in respect to the production of particular superalloy castings, however it is understood that the invention is not so limited.

Gas turbine engines are widely used in aircraft propulsion, electric power generation, and ship propulsion. In gas turbine engine applications, efficiency is a prime objective. Improved gas turbine engine efficiency can be obtained by operating at higher temperatures, however current operating temperatures in the combustor turbine sections can exceed the melting points of the superalloy materials used in combustor and turbine components. Consequently, it is a general practice to provide air cooling. Cooling is provided by flowing relatively cool air from the compressor section of the engine through passages in the components to be cooled. Such cooling comes with an associated cost in engine efficiency. Consequently, there is a strong desire to provide enhanced specific cooling, maximizing the amount of cooling benefit obtained from a given amount of cooling air. This may be obtained by the use of fine, precisely located, cooling passageway sections.

The cooling passageway sections may be cast over casting cores. Ceramic casting cores may be formed by molding a mixture of ceramic powder and binder material by injecting the mixture into hardened steel dies. After removal from the dies, the green cores are thermally post-processed to remove the binder and fired to sinter the ceramic powder together. The trend toward finer cooling features has taxed core manufacturing techniques. The fine features may be difficult to manufacture and/or, once manufactured, may prove fragile. Commonly-assigned U.S. Pat. Nos. 6,637,500 of Shah et al., 6,929,054 of Beals et al., 7,014,424 of Cunha et al., 7,134,475 of Snyder et al., and U.S. Patent Publication No. 20060239819 of Albert et al. (the disclosures of which are incorporated by reference in their entireties herein as if set forth at length) disclose use of ceramic and refractory metal core (RMC) combinations.

Various refractory metals, however, tend to oxidize at higher temperatures, e.g., in the vicinity of the temperatures used to fire the shell and the temperatures of the molten superalloys. Thus, the shell firing may substantially degrade the refractory metal cores and, thereby produce potentially unsatisfactory part internal features. Use of protective coatings on refractory metal core substrates may be necessary to protect the substrates from oxidation at high temperatures. An exemplary coating involves first applying a layer of chromium to the substrate and then applying a layer of aluminum oxide to the chromium layer (e.g., by chemical vapor deposition (CVD) techniques). U.S. Patent Publication No. 20060086479 of Parkos, Jr., et al. and European Patent Publication No. 1542045A2 of Beals et al. (the disclosures of which are incorporated by reference in their entireties herein as if set forth at length) disclose use of further coatings on refractory metal cores.

Separately, high temperature molybdenum-based alloys have been developed for use in the hot sections (e.g., combustor and turbine) of gas turbine engines for operation at temperatures up to about 2500° F. (1371° C.). U.S. Pat. Nos. 5,693,156 of Berczik and 6,652,674 of Woodard et al. (the disclosures of which are incorporated by reference herein in their entireties herein as if set forth at length) disclose molybdenum-based alloys comprising performance-effective amounts of silicon, boron, and optionally other components (hereinafter generally Mo—Si—B materials). Exemplary such material includes a mixture of molybdenum metal, molybdenum silicide, and molybdenum borosilicide phases.

### SUMMARY

One aspect of the disclosure involves a system including a chamber. A molybdenum-based substrate is within the chamber. There are means for heating the substrate. Sources of HCl, CO₂, SiCl₄, and H₂ are coupled to the chamber. There is a source of aluminum. A control system is coupled to the means for heating and the sources of HCl, CO₂, SiCl₄, and H₂. The control system is configured by at least one of hardware and software to form a molybdenum disilicide layer on the substrate and then an alumina layer on the molybdenum disilicide layer.

Another aspect of the disclosure involves a method for coating a molybdenum-based substrate. A molybdenum disilicide layer is formed on the substrate. Aluminum is reacted with hydrochloric gas to produce aluminum chloride. The aluminum chloride is reacted with hydrogen and carbon dioxide to produce alumina. A layer of the alumina is deposited atop the molybdenum disilicide layer.

The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 is a sectional micrograph of a coated substrate.

FIG. 2 is a partially schematic view of a reactor for depositing the coating of FIG. 1 on the substrate of FIG. 1.

FIG. 3 is a table of operational parameters.

FIG. 4 is an X-ray diffraction plot.

FIG. 5 is a micrograph of an alumina coating on an unsilicided substrate.

FIG. 6 is a micrograph of an alumina coating on a silicided substrate.

FIG. 7 is a table of adherence data.

Like reference numbers and designations in the various drawings indicate like elements.

### DETAILED DESCRIPTION

The chemistries of Mo—Si—B materials are or have typically been selected so that a protective borosilicate layer forms upon oxidation. Such a layer is generally stable at high temperature but is not highly water tolerant. When exposed to a high temperature, high water vapor environment (e.g., the combustor and high temperature/pressure turbine sections), the Mo—Si—B family of materials may react with the water vapor eroding the borosilicate. The oxidation-erosion cycle continues resulting in material loss. Similarly, silica-forming candidate coatings may be water intolerant.

Whereas long-term operational exposure to high water environments are relevant to such component uses of Mo—Si—B materials, other considerations are relevant to use of refractory metal cores (RMCs) in casting. As is discussed further below, relevant considerations include: non-reactivity with molten nickel; ease of coating on fine featured RMCs; and not degrading material properties of the RMCs.

Various existing coating technologies have been proposed for use with RMCs. Alumina has been a coating of choice. It may be possible to provide a family of improved coating systems and manufacturing techniques for use on Mo—Si—B components and RMCs.

Various coating chemistries and properties may be compared. For example, baseline techniques for coating alumina to RMCs may be compared with proposed techniques. A presently-proposed technique involves providing a functional gradient from substrate material through molybdenum disilicide as a base for an alumina coating. The molybdenum disilicide may provide improved adhesion of the alumina relative to a more direct application of alumina to the substrate. The functional gradient may provide a smooth transition in coefficient of thermal expansion (CTE) between the substrate and the molybdenum disilicide to reduce spalling (e.g., relative to an abrupt transition between unaffected substrate and molybdenum disilicide).

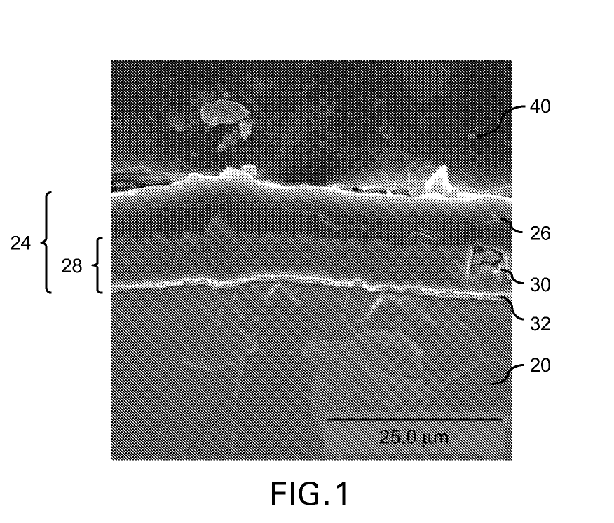

FIG. 1 shows a molybdenum-based substrate. Visualized at the illustrated scale, a coating system 24 includes an alumina outer layer 26 and a bonding layer 28. The bonding layer 28 includes a molybdenum disilicide layer 30 and a transition layer 32. Both the bonding layer 28 as a whole and the molybdenum disilicide layer 30 may have by-weight majorities of molybdenum disilicide. The transition layer 32 is between the molybdenum disilicide layer 30 and the substrate transitioning from pure molybdenum to molybdenum disilicide through several lower molybdenum silicides (e.g., Mo₃Si₅ and subsilicides). FIG. 1 also shows an epoxy mount 40.

Exemplary thicknesses of the various layers may be characterized at individual local locations or as averages (e.g., mean, median, modal). An exemplary thickness of the outer layer 26 is 5-40 μm, more narrowly 7-22 μm. An exemplary characteristic thickness of the bonding layer 28 is 2-25 μm, more narrowly 4-15 μm. An exemplary ratio of the thicknesses of the layer 26 to 28 is 0.2:1-2.5:1, more narrowly 0.45:1-1.75:1, more narrowly 0.8:1-1.2:1. Exemplary thickness of the transition layer 32 is 0.1-2.0 μm, more narrowly 0.75-1.25 μm and 1-30% of the thickness of the bonding layer 28.

The boundary between layers 26 and 30 may be defined as the location where the atomic concentration of Al drops below 38%. The boundary between layers 30 and 32 may be defined as the location where the atomic concentration of Si drops below 65%. The boundary between layers 32 and 20 may be defined as the location where the atomic concentration of Si drops to 1%.

There may also be an effective transition region (likely below the illustrated scale) between the bonding layer 28 and alumina outer layer 26. This layer is likely characterized as various aluminosilicate structures with compositions of AlₓSi_{Y}O_{Z}.

As the outer layer 26, alumina offers excellent oxide resistance and non-reactivity with molten nickel when used on RMCs for casting nickel-based superalloys.

An exemplary process for depositing the alumina is performed at relatively low temperature (e.g., 900-1100° C.). This may be contrasted with high temperature coating in the vicinity of 1500° C. or above which can degrade substrate properties (e.g., when overheated, an Mo substrate may go through a re-crystallization process, increasing brittleness). Thus, exemplary peak temperature to which the substrate is exposed may be less than 1200° C., more narrowly, less than 1100° C. or 1050° C.

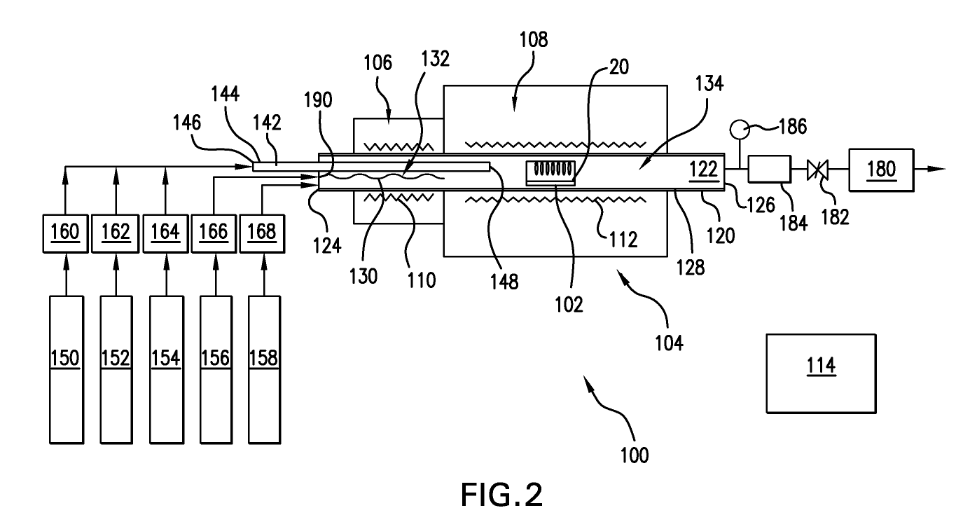

FIG. 2 shows an exemplary reactor 100 wherein the substrate 20 (e.g., Mo RMC or Mo—Si—B component) is held in a substrate holder 102. The reactor 100 includes a two-stage furnace 104 having a first stage 106 and a second stage 108. The substrate 20 is positioned within the second stage 108. Alternatively characterized, the first and second stages may be characterized as first and second furnaces, respectively. The stages 106 and 108 have respective heating elements 110 and 112 which may be independently controlled via a control system 114 (e.g., microcomputer- or microcontroller-based). A reaction chamber 120 has an interior 122. The exemplary reaction chamber 120 comprises a fused quartz (SiO₂) tube spanning the stages 106 and 108 from an upstream (inlet) end 124 to a downstream (outlet) end 126. The exemplary chamber 120 is lined with a mullite (3Al₂O₃-2SiO₂) sleeve 128 which protects the quartz tube from molybdenum disilicide coating.

An aluminum source is provided. An exemplary aluminum source comprises aluminum metal 130 (e.g., shot, foil, or the like) inside an upstream portion 132 of the chamber interior 122 (at least during the aluminum deposition). The exemplary upstream portion 132 is within the first stage 106. A downstream portion 134 is within the second stage 108.

For running a reverse water gas shift reaction (discussed below) a second chamber 142 is provided. The exemplary chamber 142 is defined by a second fused quartz tube 144 mostly within the chamber 120. The exemplary tube 144 extends from an upstream (inlet) end 146 to a downstream (outlet) end 148. The exemplary tube 134 passes within the first stage 106 to be heated by the element 110. The exemplary upstream end 146 is outside the first stage 106. The exemplary downstream end 148 is proximate an upstream end of the second stage 108 and of the downstream chamber portion 134.

As is discussed further below, various chemical sources are provided. These may include a silicon chloride liquid (SiCl₄) source 150, hydrogen gas (H₂) source 152, a carbon dioxide gas (CO₂) source 154, a hydrochloric gas (HCl) source 156, and a nitrogen gas (N₂) source 158. Output from the respective sources may be controlled by valves (e.g., mass flow controllers (MFCs 160, 162, 164, 166, and 168). FIG. 2 further shows a vacuum pump 180 coupled to the downstream end 126 of the reaction chamber 120 via throttling valve 182 and a trap 184. A pressure gauge 186 may be coupled to the chamber for measuring pressure. All these components may be coupled to and controlled by the control system 114.

In operation, the substrate 20 is placed the holder 102 and the chamber 120 is then closed. In a ramp-up preheat phase, the system is brought up to an exemplary operating temperature in the vicinity of 1000-1050° C. This phase may be performed in a non-oxidative atmosphere (e.g., hydrogen from the source 152 or a mixture of hydrogen and nitrogen from the source 158). These gases may be flowed through the chamber interior 120 and evacuated by the pump 180. An exemplary ramp-up is performed via heating exclusively from the element 112. The ramp-up may be performed in the absence of the aluminum 130 which may be introduced later. After ramp-up, silicon tetrachloride from the source 150 may be introduced to the tube 142 and hydrogen from the source 152 bubbled through and reacts with the silicon tetrachloride in the tube 142. An exemplary hydrogen flow rate and time is 100 SCCM for 15 minutes. This reaction produces silicon and hydrochloric gas:

SiCl₄+2H₂→Si+4HCl

This is discharged from the end 148. The silicon reacts with the molybdenum to form the molybdenum disilicide and other suicides. The HCL may be vented by the vacuum pump to a scrubber. The reaction may be run hydrogen-rich to avoid formation of free chlorine which could etch the substrate and interfere with silicide formation/retention. The excess hydrogen may be vented along with the HCl.

An exemplary molybdenum disilicide layer grown on the substrate 20 is 0.25 mil (6.4 μm) thick. This coating thickness and transition layer characteristics are controlled by the deposition parameters of time, temperature, and SiCl₄ flow rate. A higher flow rate will deposit more Si, yielding a thicker MoSi₂ layer, while a higher temperature and/or longer deposition time will yield a larger transition region (e.g., layer 32) from MoSi₂ to the Mo substrate. The control system may be coupled to appropriate sensors and configured via one or both of hardware and software to achieve desired coating parameters.

Aluminum oxide may be applied in the same reactor or a different reactor and may be applied immediately or after the substrate 20 has been removed from and returned to the reactor. For example, if previously removed, the now-silicided substrate may be returned and the aluminum 130 put in place. The chamber may be closed and pumped down via the pump 180 and back filled with nitrogen one or more times to remove any residual oxygen. The chamber downstream portion 134 may be brought up to a desired deposition temperature (e.g., 950-1150° C., more narrowly 1000-1100° C.) via the heating element 112. This may be performed while flowing a hydrogen-nitrogen mixture. The flow may bring a pressure up to a desired level for the ultimate reverse water gas shift reaction (e.g., 230 torr absolute, a broader range being 200 torr absolute up to atmospheric pressure (760 torr)). While flowing the hydrogen-nitrogen mixture, the chamber upstream portion 132 may be brought up to a desired chlorination temperature (e.g., 350-500° C. via the element 110). The chlorination reaction may be commenced by turning on flows from the HCl source 156 and the carbon dioxide source 154. The hydrochloric gas passes over the aluminum 130 reacting to form aluminum chloride and hydrogen gas via the reaction:

2Al+6HCl→2AlCl₃+3H₂

The aluminum chloride and hydrogen pass into the downstream portion 134 where they encounter and react with carbon dioxide discharged from the downstream end/outlet 148 of the tube 142. The reaction has two stages:

3H₂+3CO₂→3H₂O+3CO

2AlCl₃+3H₂O Al₂O₃+6HCl

The first stage of this two-step reaction is called the reverse water gas shift reaction. The second stage is an oxidation reaction. The initial reaction of hydrogen and carbon dioxide produces water and carbon monoxide. The water then reacts with the aluminum trichloride to produce aluminum oxide (alumina) and hydrochloric acid, with the alumina depositing as a coating on the substrate.

Net, the reaction produces alumina, hydrochloric acid, and carbon monoxide:

2AlCl₃+3H₂+3CO₂→Al₂O₃+6HCl+3CO

The HCl and CO are vented to the scrubber. The reaction may be run in excess hydrogen to ensure complete scavenging of free chlorine from the reaction chamber. The excess hydrogen and reaction byproducts of carbon monoxide and hydrochloric acid are exhausted from the reactor through a vacuum pump and into the scrubber.

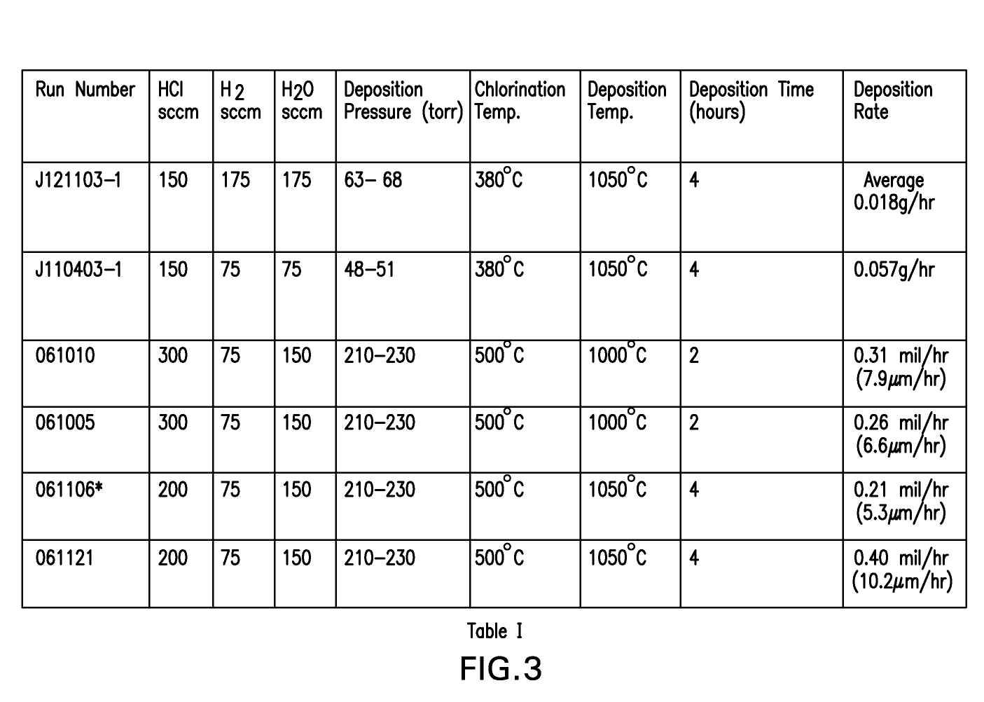

Table I of FIG. 3 shows deposition parameters used to deposit aluminum oxide coatings on test coupons of pure molybdenum. Runs 061005, 061106, and 061121 all had coupons including at least one which had previously been silicided as noted above. Run 061121 differed from the others in having an HCl injector (outlet) 190 positioned approximately 2.5 cm closer to the aluminum 130 than the other runs. This proximity increased AlCl₃ generation, leading to increased deposition rate.

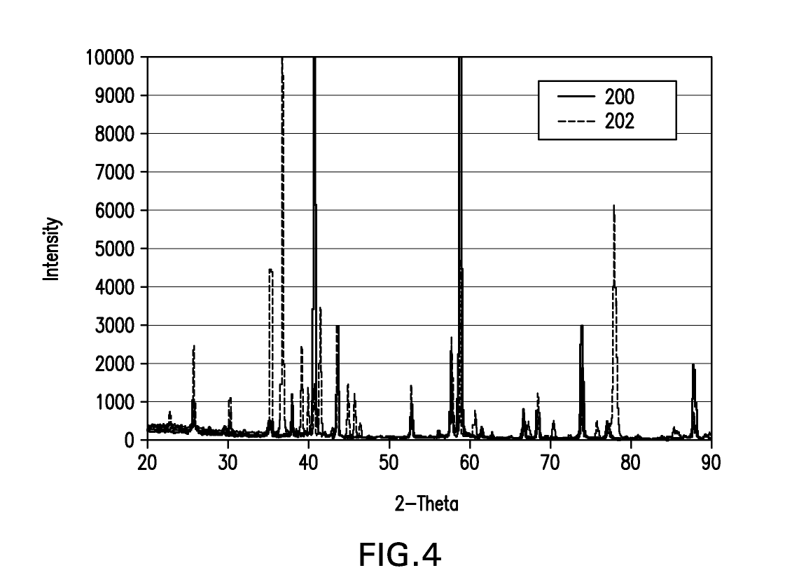

X-ray diffraction was used to characterize the degree of recrystallization of the coating. FIG. 4 shows plots 200 and 202 respectively for unsilicided and silicided coupons from runs 061010 and 061005. For both, the alumina was deposited as α-alumina. The intensity for the α-alumina crystals grown on the silicided substrates show a tendency to slightly preferentially deposited in a particular orientation.

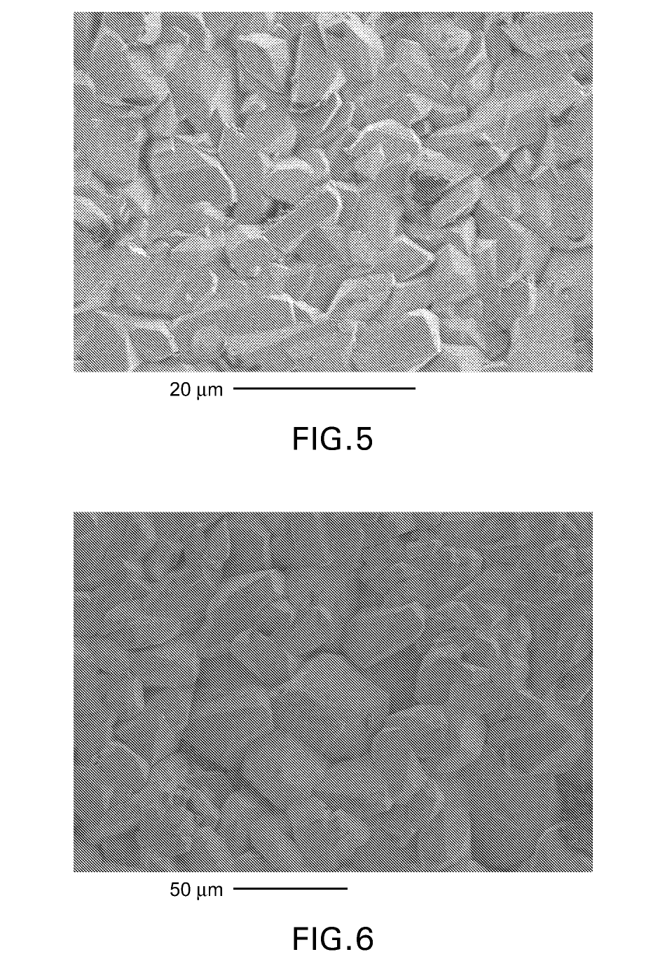

FIGS. 5 and 6 are scanning electron microscope (SEM) micrographs of the alumina coating on the unsilicided substrate and the silicided substrate, respectively. The FIG. 5 grain size is approximately 5 μm. The FIG. 6 grain size is somewhat larger (in the vicinity of 20 μm). It is not clear whether/how this is a function of the siliciding or another artifact.

Coating adherence to the substrate is a discriminator typically used to predict coating performance in service. The coating adherence is measured on witness coupons placed in each coating run using the Sebastian pull test method. A small pin with a known head area is bonded to the sample with a thermoset epoxy. The sample is then loaded in the test apparatus which measures the force required to pull the pin off the sample. In almost all cases, the coating separates from the substrate, so the measured calculated failure stress is the actual coating adherence. In a case where the epoxy bond to the coating surface fails, the calculated coating stress is a minimum coating adherence. Other contributing factors to measured coating adherence via the Sebastian pull method include coating thickness and the degree of micro-cracks in the coating. For thin coatings with micro-cracking (<0.5 mil (13 μm)), the measured adherence can be falsely high due to some epoxy wicking through the cracks and bonding directly to the substrate.

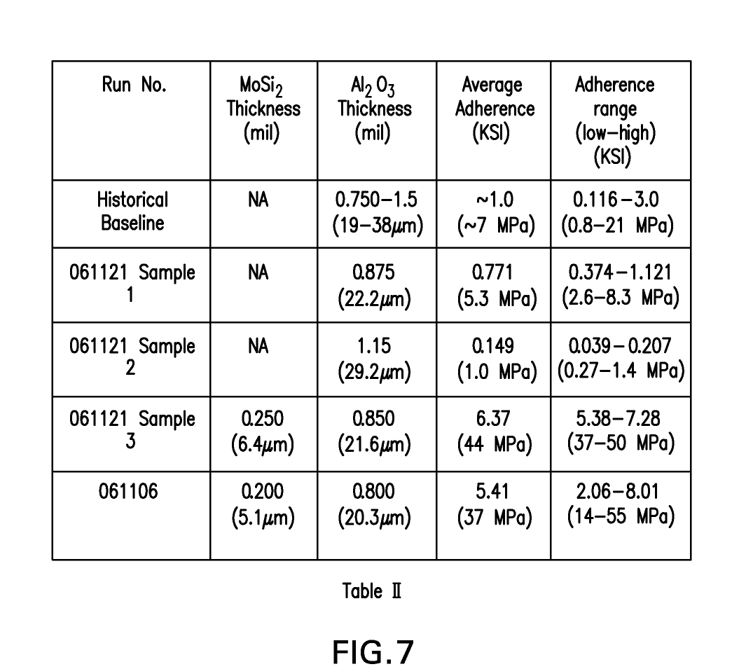

Table II of FIG. 7 shows average adherence data for samples prepared under various conditions. The normal thickness of the alumina layer 26 is approximately 1 mil for each. The presence of the layer 28 appears to improve measured coating adherence by up to six times over a similar baseline coating of alumina applied directly to the substrate. Coating adherence consistency appears also improved.

Samples with alumina deposited directly on the Mo tend to display a high variability in coating performance and a high sensitivity to location within the reactor. Alumina coatings over MoSi₂ have reduced variability with location in the reactor. Variations in coating performance for alumina on MoSi₂ between run numbers 061106 and 061121 can be attributed to changes in AlCl₃ concentrations during deposition caused by the revised gas injector location.

One or more embodiments have been described. Nevertheless, it will be understood that various modifications may be made. For example, various reactor configurations may be used. For example, mass production, including possible continuous workflow techniques may be utilized. Accordingly, other embodiments are within the scope of the following claims.

What is claimed is:

1. A system comprising:
a chamber;
a Mo-based substrate within the chamber;
means for heating the substrate;
a source of HCl coupled to the chamber;
a source of CO₂ coupled to the chamber;
a source of SiCl₄ coupled to the chamber;
a source of H₂ coupled to the chamber;
a source of aluminum; and
a control system coupled to the means for heating, the source of HCl, the source of CO₂, the source of SiCl₄, and the source of H₂, and configured by at least one of hardware and software to form a molybdenum disilicide layer on the substrate and then an alumina layer on the molybdenum disilicide layer.

2. The system of claim 1 wherein:
the control system is configured to form the molybdenum disilicide layer by flowing hydrogen from said source of H₂ through silicon tetrachloride from said source of SiCl₄.

3. The system of claim 1 wherein the control system is configured to deposit the alumina layer by:
reacting hydrochloric gas from said source of HCl with aluminum from said source of aluminum to produce aluminum chloride; and
reacting the aluminum chloride with hydrogen with carbon dioxide from said source of CO₂ and with hydrogen to produce alumina.

4. A method for coating a Mo-based substrate comprising:
forming a molybdenum disilicide layer on the substrate;
reacting aluminum with hydrochloric gas to produce aluminum chloride;
reacting the aluminum chloride with hydrogen and carbon dioxide to produce alumina; and
depositing a layer of the alumina atop the molybdenum disilicide layer.

5. The method of claim 4 wherein:
the layer of the alumina has a characteristic thickness of 5-40 μm; and
the molybdenum disilicide layer and a transition layer to the substrate combined have a characteristic thickness of 2-25 μm.

6. The method of claim 4 wherein the forming the molybdenum disilicide layer comprises:
flowing hydrogen through silicon tetrachloride.

7. The method of claim 6 wherein:
the flowing of hydrogen through silicon tetrachloride produces silicon and hydrochloric gas;
the silicon is reacted with the molybdenum-based substrate in the forming of the molybdenum disilicide layer; and
the hydrochloric gas is vented.

8. The method of claim 7 wherein:
excess said hydrogen is flowed through the silicon tetrachloride; and
the excess hydrogen is vented along with the hydrochloric gas.

9. The method of claim 8 wherein:
the reacting of the aluminum chloride with hydrogen and carbon dioxide comprises:
reacting the hydrogen and the carbon dioxide to produce water and carbon monoxide; and
reacting the aluminum chloride and the water to form the alumina and hydrochloric gas.

10. The method of claim 7 wherein:
the reacting of the aluminum chloride with hydrogen and carbon dioxide comprises:
reacting the hydrogen and the carbon dioxide to produce water and carbon monoxide; and
reacting the aluminum chloride and the water to form the alumina and hydrochloric gas.

11. The method of claim 6 wherein:
the reacting of the aluminum chloride with hydrogen and carbon dioxide comprises:
reacting the hydrogen and the carbon dioxide to produce water and carbon monoxide; and
reacting the aluminum chloride and the water to form the alumina and hydrochloric gas.

12. The method of claim 4 wherein:
the reacting of the aluminum chloride with hydrogen and carbon dioxide comprises:
reacting the hydrogen and the carbon dioxide to produce water and carbon monoxide; and
reacting the aluminum chloride and the water to form the alumina and hydrochloric gas.

13. An article comprising:
a Mo-based substrate;
a first layer comprising a by-weight majority of MoSi₂; and
a second layer comprising a by-weight majority of alumina.

14. The article of claim 13 further comprising:
a transition layer between said substrate and said first layer, the transition layer comprising a by-weight majority of a combination of molybdenum, molybdenum disilicide, and lower molybdenum silicides.

15. The article of claim 14 wherein:
the second layer has a characteristic thickness of 5-40 μm; and
the first layer and transition layer combined have a characteristic thickness of 2-25 μm.

16. The article of claim 15 wherein:
the transition layer has a characteristic thickness of 0.1-2 μm.

17. The article of claim 13 wherein:
the Mo-based substrate is an Mo—Si—B material.

18. The article of claim 13 wherein:
the Mo-based substrate consists essentially of molybdenum.

19. The article of claim 13 being a casting core.

20. The article of claim 13 being a turbine engine component.
